(19) United States
(12) Patent Application Publication
(10) Pub. No.: US 2026/0204198 A1
(43) Pub. Date: Jul. 16, 2026

(54) DISPLAY DRIVER

(71) Applicant: SAMSUNG ELECTRONICS CO., LTD., Suwon-si (KR)

(72) Inventors: Seunguk BAEK, Suwon-si, Gyeonggi-do (KR); Jihoon KIM, Suwon-si (KR); Juhyeong JIN, Suwon-si (KR); Daehyun MOON, Suwon-si (KR); Youngbae MOON, Suwon-si (KR); Keunhwa PARK, Suwon-si (KR); Seungmin YOON, Suwon-si (KR)

(73) Assignee: SAMSUNG ELECTRONICS CO., LTD., Suwon-si (KR)

(21) Appl. No.: 19/298,369

(22) Filed: Aug. 13, 2025

(30) Foreign Application Priority Data
Jan. 15, 2025 (KR) 10-2025-0006278

(51) Int. Cl. G09G 3/20; G09G 3/3291; G09G 3/36; H03F 1/56

(52) U.S. Cl. CPC G09G 3/2007; G09G 3/2092; G09G 3/3291; G09G 3/3685; G09G 3/3688; G09G 2300/0819; G09G 2310/0264; G09G 2310/027; G09G 2310/0291; G09G 2310/0297; G09G 2310/08; G09G 2330/021; H03F 1/56

(57) ABSTRACT

A display driver may include a buffer unit configured to include a plurality of source amplifiers outputting a grayscale voltage to a plurality of source lines on a display panel, a demultiplexer unit configured to include a plurality of demultiplexers connected between the plurality of source amplifiers and the plurality of source lines, and a plurality of output terminals connected to two or more source lines, among the plurality of source lines, a load circuit configured to include load elements connected to the output stages of the plurality of source amplifiers, while the input terminal and the plurality of output terminals are disconnected from each other in each of the plurality of demultiplexers, and a timing controller configured to control each of the buffer unit, the demultiplexer unit, and the load circuit.

### CROSS-REFERENCE TO RELATED APPLICATION(S

This application claims benefit of priority to Korean Patent Application No. 10-2025-0006278 filed on January 15, 2025 in the Korean Intellectual Property Office, the disclosure of which is incorporated herein by reference in its entirety.

### BACKGROUND

The present inventive concepts relate to a display driver.

Display devices used in electronic devices displaying images, such as TVs, laptop computers, monitors, and mobile devices, may include liquid crystal displays (LCDs) and organic light emitting devices (OLEDs). The display devices may include a display panel having a plurality of pixels, and a display driver for applying electric signals to the plurality of pixels, and images may be implemented by the electric signals provided by the display driver to the plurality of pixels. To reduce an area occupied by the display driver, the display driver may include a plurality of demultiplexers connected to two or more source lines. During an operation of the display driver, a time may be present in which an input terminal and a plurality of output terminals are disconnected from each other in each of the plurality of demultiplexers. During the time in which the input terminal and the plurality of output terminals of the demultiplexer are disconnected from each other, the display driver may have degraded performance due to issues such as a reduction in phase margin and an increase in power consumption caused by the generation of dynamic current.

### SUMMARY

An aspect of the present inventive concepts is to increase a phase margin by connecting a load circuit including a load element to an output stage of a source amplifier while an input terminal and a plurality of output terminals of a demultiplexer are disconnected from each other.

According to an aspect of the present inventive concepts, a display driver may include a buffer unit configured to include a plurality of source amplifiers outputting a grayscale voltage to a plurality of source lines on a display panel, the plurality of source amplifiers respectively including an input stage and an output stage outputting the grayscale voltage, a demultiplexer unit configured to include a plurality of demultiplexers connected between the plurality of source amplifiers and the plurality of source lines, the plurality of demultiplexers respectively having an input terminal connected to the output stage, and a plurality of output terminals connected to two or more source lines, among the plurality of source lines, a load circuit configured to include load elements connected to the output stages of the plurality of source amplifiers, while the input terminal and the plurality of output terminals are disconnected from each other in each of the plurality of demultiplexers, and a timing controller configured to control each of the buffer unit, the demultiplexer unit, and the load circuit.

According to an aspect of the present inventive concepts, a display driver may include an output pad configured to be connected to two or more source lines, among a plurality of source lines on a display panel, the plurality of source lines respectively connected to a plurality of pixels, a source amplifier configured to generate a grayscale voltage for one selection pixel, among the plurality of pixels, using at least one gamma voltage, a demultiplexer configured to be connected between the output pad and the plurality of source lines, configured to be connected to the two or more source lines, and configured to transmit the grayscale voltage to the one selection pixel, and a load circuit between the output pad and the source amplifier configured to include load elements. The source amplifier may be configured to output a first grayscale voltage for a first pixel, among the plurality of pixels, to the demultiplexer, and output a second grayscale voltage for a second pixel, among the plurality of pixels, to the demultiplexer. The demultiplexer may be configured to transmit the first grayscale voltage to a first source line, among the plurality of source lines, during a first time, transmit the second grayscale voltage to a second source line, among the plurality of source lines, during a second time after the first time, and be disconnected from the two or more source lines during a third time after the second time. The source amplifier and the load circuit may be connected to each other during the third time.

According to an aspect of the present inventive concepts, a display driver may include an output pad configure to be connected to two or more source lines, among a plurality of source lines disposed on a display panel, the plurality of source lines respectively connected to a plurality of pixels, a source amplifier configured to generate a grayscale voltage for one selection pixel, among the plurality of pixels, using at least one gamma voltage, a demultiplexer configured to be connected between the output pad and the plurality of source lines, configured to be connected to the two or more source lines, and configured to transmit the grayscale voltage to the one selection pixel, a bias voltage circuit configured to include a first PMOS transistor and a first buffer connected to a power supply voltage of the source amplifier, and a first NMOS transistor and a second buffer connected to a ground voltage, and a load circuit configured to include a first output switch connected between the source amplifier and the output pad, a second output switch and an output resistor connected in parallel with the first output switch, and a compensation capacitor and a compensation switch connected to a feedback path of the source amplifier. The bias voltage circuit may be configured to reduce a bias voltage from a first voltage to a second voltage, lower than the first voltage, the first output switch may be turned off, the second output switch may be turned on, and the compensation switch may be turned on, while the demultiplexer is disconnected from the two or more source lines.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a schematic block diagram illustrating an electronic device according to some example embodiments;

FIG. 2 is a schematic block diagram illustrating a display device including a display driver according to some example embodiments;

FIG. 3 is a schematic block diagram illustrating a source driver included in a display device according to some example embodiments;

FIG. 4 is a diagram illustrating a structure of a source driver according to some example embodiments;

FIGS. 5 and 6 are diagrams illustrating a structure of a source driver according to some example embodiments;

FIG. 7 is a schematic diagram illustrating a structure of a source driver according to some example embodiments;

FIG. 8 is a timing diagram illustrating an operation of a display driver according to some example embodiments;

FIG. 9 is a schematic circuit diagram illustrating a structure of a source driver according to some example embodiments;

FIGS. 10A and 10B are schematic circuit diagrams illustrating a structure of a source driver according to some example embodiments;

FIG. 11 is a timing diagram illustrating an operation of a display driver according to some example embodiments;

FIG. 12 is a diagram illustrating a structure of a source amplifier included in a display driver according to some example embodiments;

FIG. 13 is a timing diagram illustrating an operation of a display driver according to some example embodiments;

FIG. 14 is a diagram illustrating a structure of a source amplifier included in a display driver according to some example embodiments;

FIG. 15 is a timing diagram illustrating an operation of a display driver according to some example embodiments; and

FIG. 16 is a diagram illustrating a structure of a source amplifier included in a display driver according to some example embodiments.

### DETAILED DESCRIPTION

Hereinafter, preferred example embodiments of the present inventive concepts will be described with reference to the accompanying drawings.

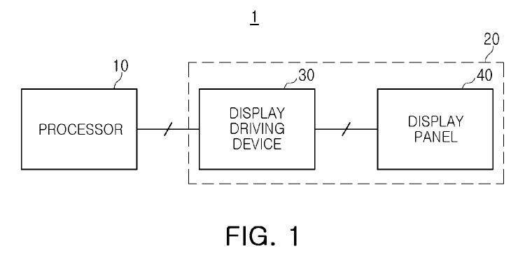

FIG. 1 is a schematic block diagram illustrating an electronic device according to some example embodiments.

Referring to FIG. 1, an electronic device 1 according to some example embodiments may include a processor 10 and a display device 20, and the display device 20 may include a display driving device 30 and a display panel 40.

The processor 10 may be an application processor (AP) for a mobile device, and may be a central processing unit (CPU) for a desktop or laptop computer. It may be interpreted that the processor 10 refers to a processing device or host having an arithmetic function. The processor 10 may generate an original image to be displayed through the display device 20, or may receive an original image from a memory, a communication module, or the like, and transmit the original image to the display driving device 30.

The display device 20 may include a display driving device 30 and a display panel 40. The display driving device 30 may include a gate driver and a source driver for inputting image data transmitted by the processor 10 to the display panel 40, and may include a timing controller controlling the gate driver and the source driver. The timing controller may control the gate driver and the source driver according to a vertical synchronization signal and a horizontal synchronization signal.

The display driving device 20 may communicate with the processor 10, based on a predetermined communication interface. In some example embodiments, the display driving device 20 may communicate with the processor 10, based on a high-speed serial interface such as a mobile industry processor interface (MIPI). According to the MIPI, the processor 10 may operate in one of a command mode for receiving only image data from the processor 10 and a video mode for receiving image data and a synchronization signal from the processor 10.

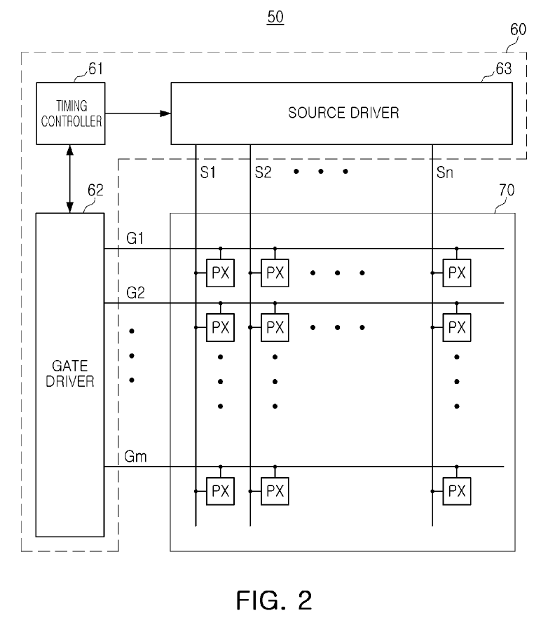

FIG. 2 is a schematic block diagram illustrating a display device including a display driver according to some example embodiments.

Referring to FIG. 2, a display device 50 may include a display driving device 60 and a display panel 70. The display driving device 60 may include a timing controller 61, a gate driver 62, and a source driver 63. The display panel 70 may include a plurality of pixels PX disposed along a plurality of gate lines G1 to Gm and a plurality of source lines S1 to Sn.

In some example embodiments, the display device 50 may display images on a per-frame basis. A time required to display a single frame may be defined as a vertical cycle, and the vertical cycle may be determined by a scan rate of the display device 50. In some example embodiments, when the scan rate of the display device 50 is 60 Hz, the vertical cycle may be 1/60 second, about 16.7 msec. When the scan rate is 144 Hz, the vertical cycle may be 1/144 second, about 6.94 msec.

During one vertical cycle, the gate driver 62 may scan each of the plurality of gate lines G1 to Gm. A time in which the gate driver 62 scans each of a plurality of gate lines G1 to Gm may be defined as a horizontal cycle. During one horizontal cycle, the source driver 63 may input a grayscale voltage to the pixels PX. The grayscale voltage may be a voltage output by the source driver 63 based on image data, and a brightness of each of the pixels PX may be determined by the grayscale voltage.

The timing controller 61 may be the core control module of the display drive device 60, controlling an operation of circuits included in each of the gate driver 62 and the source driver 63. Specifically, the timing controller 61 may generate image data, clock signals, and various control signals, transmitting image data to each driver at correct timing and controlling a switch driving timing to precisely adjust an operation in pixel PX units.

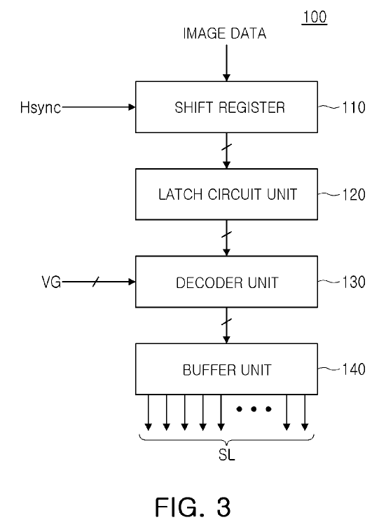

FIG. 3 is a schematic block diagram illustrating a source driver included in a display device according to some example embodiments.

Referring to FIG. 3, a source driver 100 according to some example embodiments may include a shift register 110, a latch circuit unit 120, a decoder unit 130, and a buffer unit 140. In some example embodiments, the latch circuit 120 may include a sampling circuit, sampling data, and a holding latch, storing the data sampled by the sampling circuit. Respective components 110, 120, 130, and 140 included in the source driver 100 are not limited to those in the example embodiment illustrated in FIG. 3, and may be modified in various manners.

The shift register 110 may control an operation timing of each of a plurality of sampling circuits included in the latch circuit unit 120, in response to a horizontal synchronization signal Hsync. The horizontal synchronization signal Hsync may be a signal having a predetermined cycle. The latch circuit unit 120 may sample and store image data according to a shift order of the shift register 110. The latch circuit unit 120 may output the image data to the decoder unit 130. The decoder unit 130 may include a digital analog converter (DAC).

The decoder unit 130 may receive a plurality of gamma voltages VG together with the image data. In some example embodiments, the number of the plurality of gamma voltages VG may be determined according to the number of bits of the image data. For example, when the image data is 8-bit data, the number of the plurality of gamma voltages VG may be 256 or less. When the image data is 10-bit data, the number of the plurality of gamma voltages VG may be 1024.

The buffer unit 140 may include a plurality of source amplifiers, and a plurality of unit buffers may be connected to a plurality of source lines SL. Each of the plurality of source amplifiers may include an input stage and an output stage, and the input stage may have a plurality of input terminals. The decoder unit 130 may select, based on the image data, at least some gamma voltages VG, among the plurality of gamma voltages VG, and may provide the selected gamma voltages as an input voltage to an input stage of each of the plurality of source amplifiers.

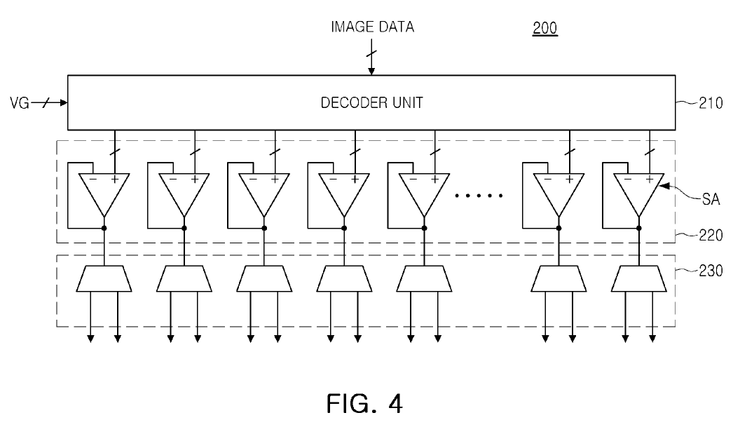

FIG. 4 is a diagram illustrating a structure of a source driver according to some example embodiments.

Referring to FIG. 4, a source driver 200 according to some example embodiments may include a decoder unit 210, a buffer unit 220, and a demultiplexer unit 230. The decoder unit 210 may receive a plurality of gamma voltages VG together with image data, and the number of the gamma voltages VG may be determined according to the number of bits of the image data. When the image data has N bits, the number of the plurality of gamma voltages VG input to the decoder unit 210 may be 2^{N} or less. The decoder unit 210, the buffer unit 220, and the demultiplexer unit 230 may be controlled by the timing controller shown in FIG. 2.

The buffer unit 220 may include a plurality of source amplifiers SA. As illustrated in FIG. 4, the source amplifier SA may include two or more non-inverted input terminals, and the decoder unit 210 may transmit at least one gamma voltage, selected from among the plurality of gamma voltages VG, to the non-inverted input terminals. An inverted input terminal of the source amplifier SA may be connected to an output terminal through a feedback path.

The demultiplexer unit 230 may include a plurality of demultiplexers. As illustrated in FIG. 4, the demultiplexer may include a single input terminal and a plurality of output terminals. The plurality of output terminals may be connected to two or more source lines, among a plurality of source lines. However, as illustrated in FIG. 4, the number of source lines connected to the demultiplexer is not limited to two, and more source lines than two source lines may be connected. The demultiplexer may be disposed between a source amplifier and two or more source lines. The demultiplexer of the demultiplexer unit 230 may receive a grayscale voltage from the source amplifier SA of the buffer unit 220, and may transmit the received grayscale voltage to one source line, among the two or more source lines connected to the plurality of output terminals.

The source driver 200 according to some example embodiments may include a plurality of demultiplexers connected to the two or more source lines, thereby reducing the number of source amplifiers SA in the source driver 200. Thus, an area occupied by the source driver 200 in the display driver may be reduced.

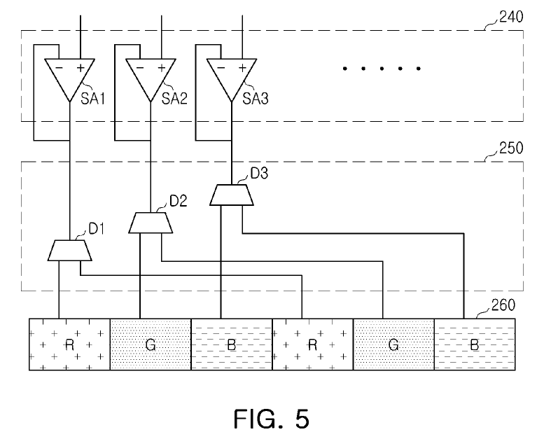

FIGS. 5 and 6 are diagrams illustrating a structure of a source driver according to some example embodiments.

Referring to FIG. 5, a source driver according to some example embodiments may include a buffer unit 240 and a demultiplexer unit 250. The buffer unit 240 may include a plurality of source amplifiers SA1 to SA3, and the demultiplexer unit 250 may include a plurality of demultiplexers D1 to D3. The plurality of demultiplexers D1 to D3 may be disposed between the plurality of source amplifiers SA1 to SA3 and a plurality of source lines. The plurality of source lines may be disposed on a display panel, and the plurality of source lines may be connected to a plurality of pixels 260, respectively.

A first source amplifier SA1, one of a plurality of source amplifiers SA1 to SA3, may be connected to a first demultiplexer D1, one of the plurality of demultiplexers D1 to D3. A plurality of output terminals included in the first demultiplexer D1 may be connected to two or more source lines. In some example embodiments, the first demultiplexer D1 may include one input terminal and two output terminals. The output terminals of the first demultiplexer D1 may be connected to a first source line and a second source line, respectively. The first source line may be connected to a first pixel, among a plurality of pixels, and the second source line may be connected to a second pixel, among the plurality of pixels. In some example embodiments, the first pixel and the second pixel may have the same color filter.

For example, referring to FIG. 5, the first demultiplexer D1 may be connected to two source lines, and two pixels, respectively connected to the two source lines, may all have a red filter. A second demultiplexer D2 may be connected to two source lines, and two pixels, respectively connected to the two source lines, may all have a green filter. A third demultiplexer D3 may be connected to two source lines, and two pixels, respectively connected to the two source lines, may all have a blue filter.

Referring to FIG. 5, the first pixel and the second pixel are illustrated as a single pixel, but the first pixel may be at least one pixel, among the plurality of pixels connected to the first source line in the display panel, and the second pixel may be at least one pixel, among the plurality of pixels connected to the second source line in the display panel.

A demultiplexer unit 280 of a source driver illustrated in FIG. 6 may be different from the demultiplexer unit 250 of the source driver illustrated in FIG. 5. Remaining components of the source driver illustrated in FIG. 6 may share technical features the same as or corresponding to those illustrated in FIG. 5. Thus, descriptions, overlapping those of the components illustrated in FIG. 5, will be simplified or omitted.

A plurality of output terminals included in a demultiplexer may be connected to two or more source lines. Pixels, respectively connected to the two or more source lines, may have different color filters. For example, an output stage of a fourth source amplifier SA4 and an input terminal of a fourth demultiplexer D4 may be connected to each other. Output terminals of the fourth demultiplexer D4 may be connected to a third source line and a fourth source line. The third source line may be connected to a third pixel, among a plurality of pixels, and the fourth source line may be connected to a fourth pixel, among the plurality of pixels. In some example embodiments, the third pixel and the fourth pixel may have different color filters. Referring to FIG. 6, the third pixel may have a red filter and the second pixel may have a blue filter.

Referring to FIG. 6, the fourth demultiplexer D4 may be connected to two source lines, and one of two pixels, connected to the two source lines, may have a red filter and the other one may have a blue filter. A fifth demultiplexer D5 may be connected to two source lines, and one of two pixels, connected to the two source lines, may have a green filter and the other one may have a red filter. A sixth demultiplexer D6 may be connected to two source lines, and one of two pixels, connected to the two source lines, may have a green filter and the other one may have a blue filter.

The source driver according to some example embodiments may include a demultiplexer unit 280 including a plurality of demultiplexers D4 to D6, and may include a plurality of demultiplexers D4 to D6 to reduce the number of a plurality of source amplifiers SA4 to SA6 included in a buffer unit 270. Each of the plurality of demultiplexers D4 to D6 may be connected to two or more source lines, and pixels, connected to the two or more source lines, may have different color filters or the same color filters. Accordingly, to minimize an area occupied by the source driver, the source driver may be disposed to connect the plurality of source amplifiers SA4 to SA6 and the plurality of demultiplexers D4 to D6 to each other, respectively.

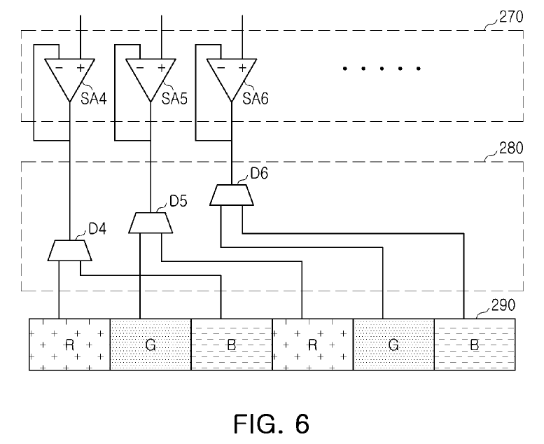

FIG. 7 is a schematic diagram illustrating a structure of a source driver according to some example embodiments.

A source driver 300 according to some example embodiments may include a source amplifier 310 and demultiplexers 330 and 340. The demultiplexers 330 and 340 may be represented by two or more switches. For example, referring to FIG. 7, the demultiplexers 330 and 340 may be represented by a first switch 330 and a second switch 340. An output pad 320 may be connected between the source amplifier 310 and the demultiplexers 330 and 340. The timing controller shown in FIG. 2 may control the first switch 330 and the second switch 340.

The output pad 320 may be connected to two or more source lines, among a plurality of source lines disposed on a display panel. The plurality of source lines may be connected to a plurality of pixels, respectively. The output pad 320 may transmit a grayscale voltage output from an output stage of the source amplifier 310 to one of the two or more source lines. Referring to FIG. 7, the output pad 320 may be connected to a first source line and a second source line. For example, the output pad 320 may transmit a first grayscale voltage output from the source amplifier 310 to the first source line through the first switch 330.

A load 325 of the output stage generated due to routing from a display driver to the display panel may be observed at the output stage of the source amplifier 310. The load 325 of the output stage may include a resistance and a capacitance. The load 325 of the output stage may be observed when the demultiplexer is turned off, that is, when both the first switch 330 and the second switch 340 are turned off.

A load 335 of the first source line may be observed when the first switch 330 is turned on and the second switch 340 is turned off. The load 335 of the first source line may be a load having a value significantly greater than that of the load 325 of the output stage. Referring to FIG. 7, the load 335 of the first source line may include a single resistance and a single capacitance. The first source line may be connected to some pixels, among the plurality of pixels, and thus may include a load component for each pixel and, consequently, may include a plurality of load components.

A load 345 of the second source line may be observed when the first switch 330 is turned off and the second switch 340 is turned on. In a similar manner to the load 335 of the first source line, the load 345 of the second source line may be a load having a value significantly greater than that of the load 325 of the output stage. In addition, the load 345 of the second source line may include a plurality of loads.

The demultiplexers 330 and 340 included in the source driver 300 according to some example embodiments may have a time in which an input terminal and a plurality of output terminals are disconnected from each other. For example, the timing controller may disconnect the input terminal and the plurality of output terminals from each other in each of the plurality of demultiplexers by a demultiplexer control signal. During the time in which the input terminals of the demultiplexers 330 and 340 are disconnected from each other, a phase margin may be reduced due to a resistance and a capacitance resulting from routing from the display driver to the display panel, which may cause ringing, in which subsequently an input signal oscillates. When ringing occurs in a signal, a dynamic current may be generated, unnecessary power may be consumed, and the display driver may have degraded performance.

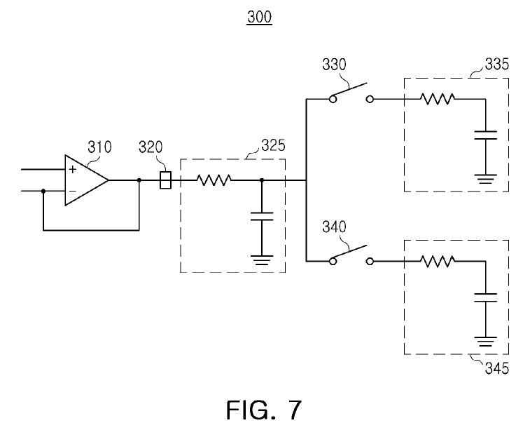

FIG. 8 is a timing diagram illustrating an operation of a display driver according to some example embodiments.

The display panel may be operated by a vertical synchronization signal having a vertical cycle and a horizontal synchronization signal HSYNC having a horizontal cycle. The vertical cycle may include a first vertical porch time, a vertical active time, and a second vertical porch time, and the first vertical porch time may include a vertical response time. In some example embodiments, the first vertical porch time may be a vertical back porch time before the vertical active time, and the second vertical porch time may be a vertical front porch time after the vertical active time.

The horizontal cycle may include a first horizontal porch time, a horizontal active time, and a second horizontal porch time, and the first horizontal porch time may include a horizontal response time. In some example embodiments, the first horizontal porch time may be a horizontal back porch time before the horizontal active time, and the second horizontal porch time may be a horizontal front porch time after the horizontal active time.

Scanning of a plurality of gate lines included in a display panel and data input for a pixel connected to the scanned gate line may be performed during the vertical and horizontal active times. That is, the gate lines may be sequentially scanned during the vertical active time, and data input for a pixel connected to the scanned gate line may be performed during the horizontal active time.

Referring to FIG. 8, a portion of a horizontal active time of the horizontal synchronization signal HSYNC may be illustrated. During the vertical and horizontal active times, an input terminal and a plurality of output terminals of a demultiplexer may be connected to each other. The input terminal and each of the plurality of output terminals of the demultiplexer may be connected each other through switches. In some example embodiments, the switches may be implemented as PMOS transistors. The PMOS transistor may perform a switching operation in which a source and a drain are connected to each other when a voltage input to a gate is low, and the source and the drain are disconnected from each other when the voltage input to the gate is high. When a low voltage is input to a gate of the PMOS transistor, a switch may be turned on, and the input terminal may be connected to one of the plurality of output terminals.

In some example embodiments, a transistor in a display driver may be implemented as a CMOS transistor, and a transistor in a display panel may be implemented as a PMOS transistor. Referring to FIGS. 7 and 8, the first switch 330 and the second switch 340 illustrated in FIG. 7 may be implemented as PMOS transistors, respectively. A voltage input to a gate of the PMOS transistor included in the first switch 330 may be a CLA, and a voltage input to a gate of the PMOS transistor included in the second switch 340 may be a CLB. In a time t1 in which the CLA is a low voltage and the CLB is a high voltage, the first switch 330 may be turned on and the second switch 340 may be turned off. In a time t2 in which the CLA is a high voltage and the CLB is a low voltage, the first switch 330 may be turned off and the second switch 340 may be turned on. In a time t3 in which both the CLA and the CLB are high voltages, both the first switch 330 and the second switch 340 may be turned off.

The demultiplexer may include a plurality of switches connecting the input terminal and each of the plurality of output terminals to each other. Referring to FIG. 8, an operation of the demultiplexer may include the times t1 and t2 in which one of the plurality of switches is turned on and the time t3 in which all of the plurality of switches are turned off. During the time t3 in which all of the plurality of switches are turned off, a threshold voltage of each of a plurality of pixels included in the display panel may be compensated. When one of the plurality of switches is turned on, the input terminal of the demultiplexer may be connected to one of the plurality of output terminals. When all of the plurality of switches are turned off, the input terminal and the plurality of output terminals of the demultiplexer may be disconnected from each other.

Referring to FIGS. 7 and 8, the source amplifier 310 may output a first grayscale voltage for a first pixel, among the plurality of pixels, to the demultiplexer, and may output a second grayscale voltage for a second pixel, among the plurality of pixels, to the demultiplexer. The demultiplexer may transmit the first grayscale voltage to a first source line among a plurality of source lines during a first time t1, and may transmit the second grayscale voltage to a second source line during a second time t2 after the first time t1. During a third time t3 after the second time t2, the demultiplexer may be disconnected from two or more source lines. In some example embodiments, an interval between the first time t1 and the second time t2 may be shorter than the third time t3. During the third time t3, a phase margin may be reduced due to a load resulting from routing from the display driver to the display panel observed from an output stage of the source amplifier. When the phase margin is reduced, oscillation and ringing may occur in a voltage output from the source amplifier, and dynamic current may flow through a source driver. This dynamic current may increase unnecessary power consumption and cause electromagnetic interference (EMI), thereby degrading the performance and reliability of the display driver.

The display driver according to some example embodiments may increase the phase margin during the third time t3. During the third time t3, a load circuit including load elements may be connected to the output stage of the source amplifier. The load elements may include at least one of a switch, a resistor, and a capacitor. A bandwidth of the display driver may be reduced through the load elements, thereby increasing the phase margin. When the phase margin is increased, dynamic current may be reduced, thereby improving the performance and reliability of the display driver.

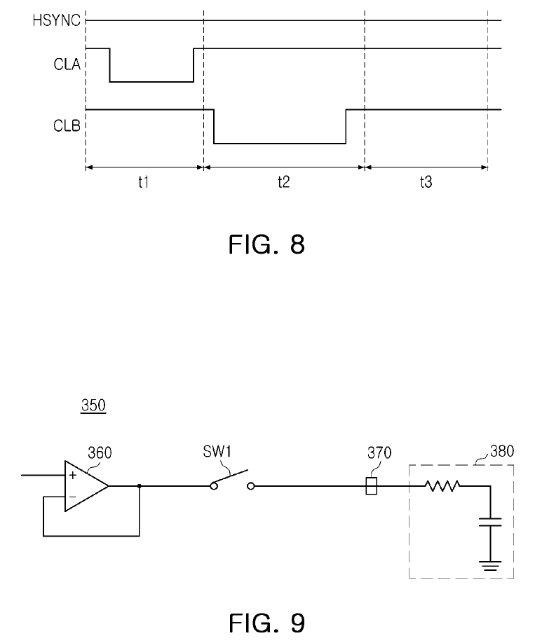

FIG. 9 is a schematic circuit diagram illustrating a structure of a source driver according to some example embodiments.

A source driver 350 according to some example embodiments may share technical features the same as or corresponding to those of the source driver 300 illustrated in FIG. 7. Thus, descriptions, overlapping those of the components illustrated in FIG. 7, will be simplified or omitted.

The source driver 350 according to some example embodiments may include a source amplifier 360 and an output pad 370. The output pad 370 may be connected to an input terminal of a demultiplexer. While the input terminal and a plurality of output terminals of the demultiplexer are disconnected from each other, a load 380 of an output stage including a resistance and a capacitance resulting from routing from a display driver to a display panel may be observed at the output stage of the source amplifier 360. While the input terminal and the plurality of output terminals of the demultiplexer are disconnected from each other, a phase margin may be reduced by the load 380 of the output stage.

Referring to FIG. 9, a load circuit included in the source driver 350 according to some example embodiments may include a first output switch SW1 connected between the source amplifier 360 and the output pad 370. In some example embodiments, the first output switch SW1 may be implemented as a CMOS transistor. While the input terminal and the plurality of output terminals of the demultiplexer are disconnected from each other, when the first output switch SW1 is turned off, a load generated by routing from the display driver to the display panel may not be electrically disconnected and observed. The timing controller may disconnect the input terminal and the plurality of output terminals from each other in each of the plurality of demultiplexers by a demultiplexer control signal, and turn on the first output switch SW1 by a first output switch control signal.

A state in which the load 380 of the output stage is electrically disconnected may correspond to a circuit in a state in which no load is present. The circuit in a state in which no load is present may be considered as a one-pole system. In the one-pole system, a phase margin may be increased. Accordingly, while the input terminal and the plurality of output terminals of the demultiplexer are disconnected from each other, the first output switch SW1 may be turned off. Thus, the source driver 350 may be configured as the one-pole system, and the phase margin may be increased.

The source driver 350 according to some example embodiments may connect the first output switch SW1 between the source amplifier 360 and am output pad 370, thereby improving the phase margin. While the input terminal and the plurality of output terminals of the demultiplexer are disconnected from each other, the first output switch SW1 may be turned off, thereby minimizing ringing in a voltage output from the source amplifier 360, which is caused by the load 380 of the output stage. In addition, improving the phase margin may prevent the generation of dynamic current, thereby reducing unnecessary power consumption and improving the performance and reliability of the display driver.

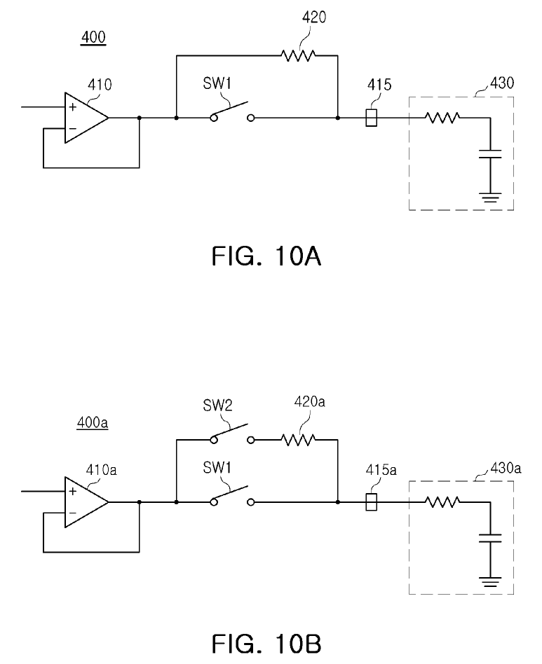

FIGS. 10A and 10B are schematic circuit diagrams illustrating a structure of a source driver according to some example embodiments.

Referring to FIGS. 10A and 10B together, source drivers 400 and 400a according to some example embodiments share technical feature the same as or corresponding to those of the source driver 350 illustrated in FIG. 9. Thus, descriptions, overlapping those of the components illustrated in FIG. 9, will be simplified or omitted.

Referring to FIG. 10A, a load circuit included in the source driver 400 according to some example embodiments may further include an output resistor 420 connected in parallel with a first output switch SW1 between an output stage of a source amplifier 410 and an input terminal of a demultiplexer. For example, a timing controller may disconnect an input terminal and a plurality of output terminals from each other in each of a plurality of demultiplexers by a demultiplexer control signal, and turn off the first output switch SW1 by a first output switch control signal. The timing controller may connect the input terminal and the plurality of output terminals from each other in each of the plurality of demultiplexers by the demultiplexer control signal, and turn on the first output switch SW1 by the first output switch control signal. For example, the first output switch SW1 may be positioned in a display driver, and thus may be implemented as a CMOS transistor.

The source driver 400 according to some example embodiments may include the output resistor 420 having a relatively high resistance value, thereby increasing a phase margin. The output resistor 420 may have a resistance value greater than a value of a resistance included in a load 430 of an output stage. The output resistor 420 may be added to the output stage of the source amplifier 410, and thus a zero may be shifted to a lower frequency, thereby increasing the phase margin. For example, while the input terminal and the plurality of output terminals are disconnected from each other in each of the plurality of demultiplexers, the phase margin may be increased when the output resistor 420 having a resistance value of 10 kΩ or more is connected to the output stage of the source amplifier 410.

Referring to FIG. 10B, a load circuit included in the source driver 400a according to some example embodiments may further include a second output switch SW2 connected in parallel with the first output switch SW1 between an output stage of the source amplifier 410a and the input terminal of the demultiplexer, and an output resistor 420a connected between the second output switch SW2 and the input terminal of the demultiplexer. In some example embodiments, both the first output switch SW1 and the second output switch SW2 may be implemented as CMOS transistors.

A timing controller may disconnect the input terminal and the plurality of output terminals from each other in each of the plurality of demultiplexers by a demultiplexer control signal, turn off the first output switch SW1 by a first output switch control signal, and turn on the second output switch SW2 by a second output switch control signal. When the output resistor 420a having a relatively high resistance value is connected to the output stage of the source amplifier 410a, a transfer function may form a zero, causing an output of 0. The zero may increase a phase margin of the source driver 400a.

In some example embodiments, the timing controller may connect the input terminal and the plurality of output terminals in each of the plurality of demultiplexers by the demultiplexer control signal, turn on the first output switch SW1 by the first output switch control signal, and turn on the second output switch SW2 by the second output switch control signal. Even when the second output switch SW2, connected to the output resistor 420a having a relatively high resistance value, is turned on, a gray voltage output from the source amplifier 410a may be transmitted to an output pad 415a after passing through the first output switch SW1 having a low resistance value. Accordingly, the gray voltage output from the source amplifier 410a may be transmitted to the input terminal of the demultiplexer after passing through the output pad 415a.

In some example embodiments, the timing controller may connect the input terminal and the plurality of output terminals from each other in each of the plurality of demultiplexers by the demultiplexer control signal, turn on the first output switch SW1 by the first output switch control signal, and turn off the second output switch SW2 by the second output switch control signal. As the second output switch SW2 is turned off, the output stage of the source amplifier 410a may be disconnected from the output resistor 420a. Accordingly, the grayscale voltage output from the source amplifier 410a may be input to the input terminal of the demultiplexer after passing through the output pad 415a.

Referring to FIG. 10B, the source driver 400a according to some example embodiments may be connected to a load circuit including a first switch SW1, a second switch SW2, and an output resistor 420a while the input terminal and the plurality of output terminals of the demultiplexer are disconnected from each other. While the input terminal and a plurality of output terminals of the demultiplexer are disconnected from each other, the first switch SW1 may be turned off, and the second switch SW2 may be turned on, such that the output stage of the source amplifier 410a and the output resistor 420a may be connected to each other. The output resistor 420a having a relatively high resistance value may be connected to the output stage of the source amplifier 410a. Thus, a phase margin of the source driver 400a may be increased, and unnecessary power consumption caused by the generation of dynamic current may be prevented, thereby improving the performance and reliability of the display driver.

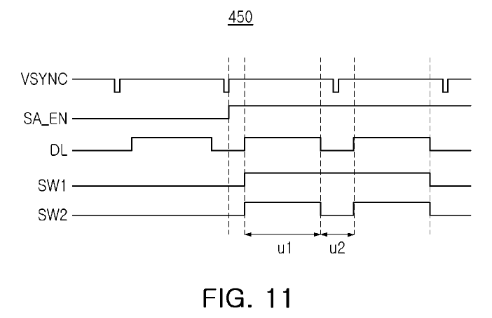

FIG. 11 is a timing diagram illustrating an operation of a display driver according to some example embodiments.

Referring to FIGS. 10B and 11, FIG. 11 may be a timing diagram illustrating an operation for the second output switch SW2 included in the source driver 400a illustrated in FIG. 10B.

As described with reference to FIG. 8, a display panel may be operated by a vertical synchronization signal VSYNC having a vertical cycle and a horizontal synchronization signal having a horizontal cycle. The vertical cycle may include a first vertical porch time, a vertical active time, and a second vertical porch time, and the first vertical porch time may include a vertical response time. Referring to FIG. 11, when the vertical synchronization signal VSYNC is a low voltage, the vertical cycle may be a first vertical porch time. After the first vertical porch time, when the vertical synchronization signal VSYNC is a high voltage, the vertical cycle may be a vertical active time, and then a second vertical porch time.

Scanning of a plurality of gate lines included in a display panel and data input for a pixel connected to the scanned gate line may be performed during vertical and horizontal active times. When a source amplifier activation signal SA_EN is input to a source amplifier during the vertical and horizontal active times, the source amplifier may be activated and output a grayscale voltage.

The operation of the display driver may have a display time in which data is input to the display panel, and a display porch time in which data is not input to the display panel. A display time u1 may be a time required to input data to all lines of the display panel during the vertical and horizontal active times. A display porch time u2 may be a time in which no data is input to each line of the display panel. In some example embodiments, the display porch time u2 may have a time overlapping the first vertical porch time and the second vertical porch time. Referring to FIG. 11, DL may represent the display time as “1,” and the display porch time as “0.”

According to some example embodiments, the second output switch SW2 may be turned on during the display time u1 in which data is input to the display panel, and the second output switch SW2 may be turned off during the display porch time u2 excluding the display time. Referring to FIGS. 10B and 11, the second output switch SW2 may be turned off during the display porch time u2, thereby preventing an unnecessary flow of current that may flow through the output resistor 420a in the activated source amplifier 410a. In some example embodiments, the first output switch SW1 may be turned on during both the display time u1 and the display porch time u2.

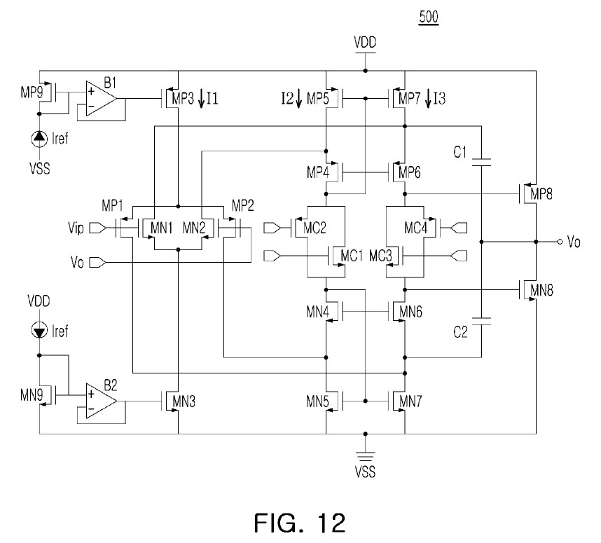

FIG. 12 is a diagram illustrating a structure of a source amplifier included in a display driver according to some example embodiments.

FIG. 12 may be a schematic circuit diagram illustrating an input stage 500 included in a source amplifier according to some example embodiments. The input stage 500 may operate as an amplifying circuit, and may have a folded cascode structure.

Referring to FIG. 12, the input stage 500 may include first to eighth PMOS transistors MP1 to MP8, first to eighth NMOS transistors MN1 to MN8, and first to fourth control transistors MC1 to MC4. However, a circuit of the input stage 500 is not limited to that illustrated in FIG. 12, and may be implemented as a circuit having a structure different from that of the circuit illustrated in FIG. 12 in some example embodiments. In some example embodiments illustrated in FIG. 12, a value of each of the first to third currents I1 to I3 flowing through the input stage 500 may vary depending on image data input to a decoder unit connected to a source amplifier.

The input stage 500 according to some example embodiments may further include a bias voltage circuit including a ninth PMOS transistor MP9 and a first buffer B1 connected in series with each other, and a ninth NMOS transistor MN9 and a second buffer B2 connected in series with each other. The bias voltage circuit may include a current mirror, and a reference current Iref may increase or reduce a bias voltage of the circuit by adjusting an operation of a transistor through the current mirror.

Specifically, the ninth PMOS transistor MP9 may be used to mirror the reference current Iref, and the reference current Iref may be provided between a drain of the ninth PMOS transistor MP9 and a ground voltage VSS. A source of the ninth PMOS transistor MP9 may be connected to a power supply voltage VDD, and a gate of the ninth PMOS transistor MP9 may be connected to the drain. The first buffer B1 may stably maintain a gate voltage of the ninth PMOS transistor MP9 or rapidly change the voltage. A positive input terminal (+) of the first buffer B1 may be connected to the gate of the ninth PMOS transistor MP9, and a negative input terminal (-) of the first buffer B1 may be connected to an output terminal of the first buffer B1. The output terminal of the first buffer B1 may be connected to a gate of a third PMOS transistor MP3.

Similarly, the ninth NMOS transistor MN9 may be used to mirror the reference current Iref, and the reference current Iref may be provided between a drain of the ninth NMOS transistor MN9 and the power supply voltage VDD. A source of the ninth NMOS transistor MN9 may be connected to the ground voltage VSS, and a gate of the ninth NMOS transistor MN9 may be connected to the drain. The second buffer B2 may stably maintain a gate voltage of the ninth NMOS transistor MN9 or rapidly change the voltage. A positive input terminal (+) of the second buffer B2 may be connected to the gate of the ninth NMOS transistor MN9, and a negative input terminal (-) of the second buffer B2 may be connected to an output terminal of the second buffer B2. The output terminal of the second buffer B2 may be connected to a gate of a third NMOS transistor MN3.

In the input stage 500 according to some example embodiments, the bias voltage circuit may reduce the bias voltage from a first voltage to a second voltage while an input terminal and a plurality of output terminals of a demultiplexer, connected to an output stage of the source amplifier, are disconnected from each other. In some example embodiments, the first voltage may be three times the second voltage. In other words, the bias voltage circuit may reduce the bias voltage from the first voltage to the second voltage, one-third of the first voltage.

While an input terminal and a plurality of output terminals are connected to each other in each of a plurality of demultiplexers, the bias voltage circuit may increase the bias voltage from the second voltage to the first voltage. In some example embodiments, the bias voltage circuit may further include a bias buffer. The bias voltage circuit may rapidly increase the bias voltage from the second voltage to the first voltage using the bias buffer.

A display driver according to some example embodiments may reduce the bias voltage while the input terminal and the plurality of output terminals are disconnected from each other in each of the plurality of demultiplexers, thereby reducing a bandwidth and increasing a phase margin. For example, when the bias voltage is reduced to one-third, the bandwidth may be reduced by a factor of root 3, thereby increasing the phase margin. The phase margin may be increased using the bias voltage circuit, and unnecessary power consumption caused by the generation of dynamic current may be prevented, thereby improving the performance and reliability of the display driver.

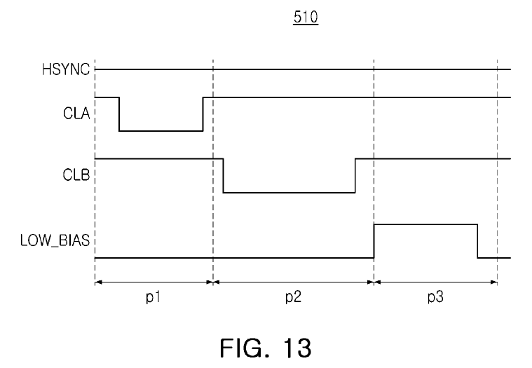

FIG. 13 is a timing diagram illustrating an operation of a display driver according to some example embodiments.

Referring to FIG. 13, a timing diagram 510 according to some example embodiments may share technical features the same as or corresponding to those of the timing diagram illustrated in FIG. 8. Thus, descriptions, overlapping those of the components illustrated in FIG. 8, will be simplified or omitted.

A demultiplexer according to some example embodiments may be connected to an output stage of a source amplifier, and may include an input terminal and a plurality of output terminals. The plurality of output terminals may be connected to two or more source lines, among a plurality of source lines.

For example, the demultiplexer may be connected to a first source line and a second source line, among the plurality of source lines. During a time p1 in which a first switch, connected to the first source line, is turned on, the demultiplexer may receive a first grayscale voltage output from the source amplifier and transmit the first grayscale voltage to the first source line. During a time p2 in which a second switch, connected to the second source line, is turned on, the demultiplexer may receive a second grayscale voltage output from the source amplifier and transmit the second grayscale voltage to the second source line. The demultiplexer may have a time p3 in which the input terminal and the plurality of output terminals are disconnected from each other.

Referring to FIG. 13, a bias voltage may be reduced (LOW_BIAS) and a phase margin may be increased during the time p3 in which the input terminal and the plurality of output terminals of the demultiplexer are disconnected from each other. During the time p3 in which the input terminal and the plurality of output terminals of the demultiplexer are disconnected from each other, a bias voltage circuit may be connected to the source amplifier, thereby reducing the bias voltage. When the bias voltage is reduced, a bandwidth may be reduced. When the bandwidth is reduced, the phase margin may be increased.

Accordingly, a display driver according to some example embodiments may increase the phase margin by reducing the bias voltage using the bias voltage circuit, thereby improving the performance and reliability of the display driver and reducing unnecessary power consumption caused by the generation of dynamic current.

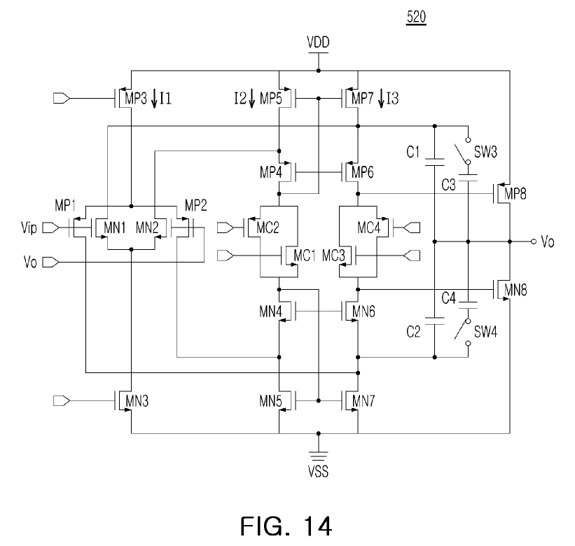

FIG. 14 is a diagram illustrating a structure of a source amplifier included in a display driver according to some example embodiments.

Referring to FIG. 14, an input stage 520 according to some example embodiments may share technical features the same as or corresponding to those of the input stage 500 illustrated in FIG. 12. Thus, descriptions, overlapping those of the components illustrated in FIG. 12, will be simplified or omitted.

Referring to FIG. 14, the input stage 520 according to some example embodiments may include a load circuit disposed between an input stage and an output stage. The load circuit may include first compensation capacitors C1 and C2 and second compensation capacitors C3 and C4 disposed in parallel between the input stage and the output stage. Compensation switches SW3 and SW4 may be disposed between the input stage and the second compensation capacitors C3 and C4. In some example embodiments, the compensation switches SW3 and SW4 may be disposed between the output stage and the second compensation capacitors C3 and C4.

A timing controller may disconnect an input terminal and a plurality of output terminals in each of a plurality of demultiplexers by a demultiplexer control signal, and turn on the compensation switch SW3 and SW4 by a compensation switch control signal. The timing controller may connect the input terminal and the plurality of output terminals in each of the plurality of demultiplexers by the demultiplexer control signal, and turn off the compensation switch SW3 and SW4 by the compensation switch control signal.

The input stage 520 according to some example embodiments may include first compensation capacitors C1 and C2 and second compensation capacitors C3 and C4 connected to a feedback path between the input stage and the output stage to increase a phase margin while the input terminal and the plurality of output terminals of the demultiplexer are disconnected from each other. The first compensation capacitors C1 and C2 and the second compensation capacitors C3 and C4 may be connected in parallel with an output stage of a source amplifier, thereby increasing a total capacitance. When the capacitance is increased, a dominant pole may be shifted to a lower frequency, reducing the bandwidth and thereby increasing the phase margin.

In some example embodiments, the first compensation capacitors C1 and C2 and the second compensation capacitors C3 and C4 may have the same capacitance value. When the first compensation capacitors C1 and C2 and the second compensation capacitors C3 and C4 have the same capacitance value, the phase margin may be increased by three times or more. Accordingly, while the input terminal and the plurality of output terminals of the demultiplexer are disconnected from each other, the first compensation capacitors C1 and C2 and the second compensation capacitors C3 and C4 may be connected in parallel with the output stage of the source amplifier to increase the phase margin. By increasing the phase margin, an increase in power consumption caused by the generation of dynamic current may be prevented, thereby improving the performance and reliability of the display driver.

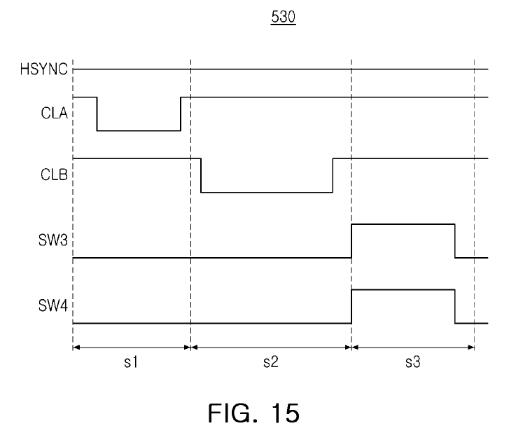

FIG. 15 is a timing diagram illustrating an operation of a display driver according to some example embodiments.

Referring to FIG. 15, a timing diagram 530 according to some example embodiments may share technical features the same as or corresponding to those of the timing diagram illustrated in FIG. 8. Thus, descriptions, overlapping those of the components illustrated in FIG. 8, will be simplified or omitted.

A demultiplexer according to some example embodiments may be connected to an output stage of a source amplifier, and may include an input terminal and a plurality of output terminals. The plurality of output terminals may be connected to two or more source lines, among a plurality of source lines. For example, the demultiplexer may be connected to a first source line and a second source line, among the plurality of source lines. During a time p1 in which a first switch, connected to the first source line, is turned on, the demultiplexer may receive a first grayscale voltage output from the source amplifier and transmit the first grayscale voltage to the first source line. During a time p2 in which a second switch, connected to the second source line, is turned on, the demultiplexer may receive a second grayscale voltage output from the source amplifier and transmit the second grayscale voltage to the second source line. The demultiplexer may have a time p3 in which the input terminal and the plurality of output terminals are disconnected from each other.

Referring to FIGS. 14 and 15, a compensation capacitor may be connected to the output stage of the source amplifier to increase a phase margin during the time s3 in which the input terminal and the plurality of output terminals of the demultiplexer are disconnected from each other. When first compensation capacitors C1 and C2 and second compensation capacitors C3 and C4 are connected in parallel with the output stage, a total capacitance may be increased. When the capacitance is increased, a dominant pole may be shifted to a lower frequency, reducing the bandwidth and thereby increasing the phase margin.

A display driver according to some example embodiments may connect a load circuit including a compensation capacitance to the output stage of the source amplifier while the input terminal and the plurality of output terminals of the demultiplexer are disconnected from each other, thereby increasing the phase margin. The phase margin may be increased and an increase in power consumption caused by the generation of dynamic current may be prevented, thereby improving the performance and reliability of the display driver.

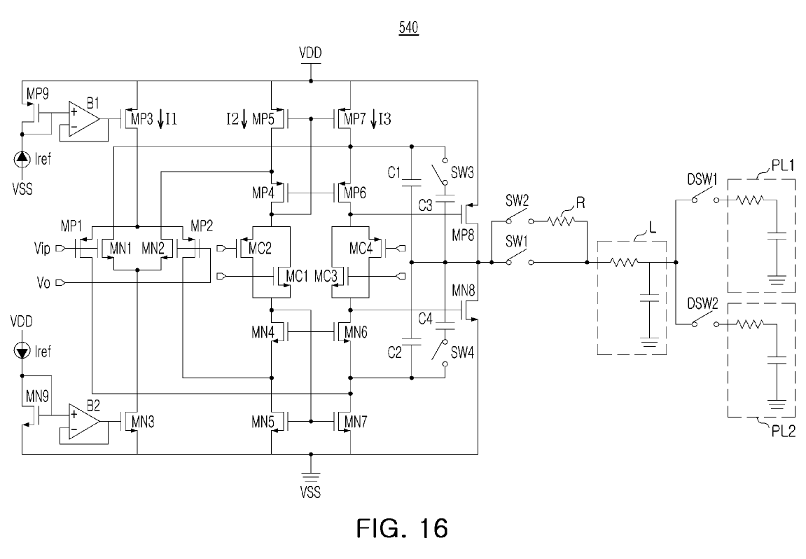

FIG. 16 is a diagram illustrating a structure of a source amplifier included in a display driver according to some example embodiments.

Referring to FIG. 16, a display driver 540 according to some example embodiments may share technical features the same as or corresponding to those of the input stage 500 illustrated in FIG. 12. Thus, descriptions, overlapping those of the components illustrated in FIG. 12, will be simplified or omitted.

The display driver 540 according to some example embodiments may include a plurality of source amplifiers outputting a grayscale voltage to a plurality of source lines disposed on a display panel, and each of the plurality of source amplifiers may include a buffer unit including an input stage and an output stage outputting a grayscale voltage. In addition, the display driver 540 may include a plurality of demultiplexers connected between the plurality of source amplifiers and the plurality of source lines, and each of the plurality of demultiplexers may include a demultiplexer unit having a single input terminal, connected to an output stage, and a plurality of output terminals connected to two or more source lines, among the plurality of source lines. Finally, the display driver 540 may include a load circuit including load elements connected to output stages of the plurality of source amplifiers. While the input terminal and the plurality of output terminals are disconnected from each other in each of the plurality of demultiplexers, the load circuit may be connected to the output stages of the plurality of source amplifiers. The load elements included in the load circuit may increase a phase margin of the display driver 540.

Referring to FIG. 16, the output stage of the source amplifier may be connected to the demultiplexer, and the demultiplexer may be implemented by two switches DSW1 and DSW2. When a first switch DSW1 of the demultiplexer is turned on, a load PL1 of a first source line may be observed on the display panel. When a second switch DSW2 of the demultiplexer is turned on, a load PL2 of a second source line may be observed on the display panel. When both the first switch DSW1 and the second switch DSW2 of the demultiplexer are turned off, only a load L of the output stage may be observed on the output stage of the source amplifier.

A load circuit including a switch and a resistor may be connected to the output stage of the source amplifier, while the input terminal and the plurality of output terminals are disconnected from each other in each of the plurality of demultiplexers. A first output switch SW1, and a second output switch SW2 and an output resistor R, connected in parallel with the first output switch SW1, may be connected to the output stage of the source amplifier. While the input terminal and the plurality of output terminals of the demultiplexer, connected to the output stage of the source amplifier, are disconnected from each other, the first output switch SW1 may be turned off, and the second output switch SW2 may be turned on. The output resistor R may shift a zero to a low frequency, thereby increasing a phase margin.

The load circuit including the switch and the capacitor may be connected to the output stage of the source amplifier. First compensation capacitors C1 and C2 and second compensation capacitors C3 and C4 may be connected to the output stage of the source amplifier. Compensation switches SW3 and SW4 may be disposed between the second compensation capacitors C3 and C4 and the output stage. The first compensation capacitors C1 and C2 and the second compensation capacitors C3 and C4 may be connected in parallel with each other. While the input terminal and the plurality of output terminals of the demultiplexer are disconnected from each other, the compensation switches SW3 and SW4 may be turned on, and the first compensation capacitors C1 and C2 and the second compensation capacitors C3 and C4 may be connected in parallel with each other, thereby increasing a capacitance to shift a dominant pole to a lower frequency, and reducing a bandwidth to increase the phase margin.

A bias voltage circuit may be connected between the input stage and the output stage of the source amplifier. The bias voltage circuit may include a ninth PMOS transistor MP9, a first buffer B1, a ninth NMOS transistor MN9, and a second buffer B2. While the input terminal and the plurality of output terminals of the demultiplexer are disconnected from each other, the bias voltage circuit may reduce a bias voltage of the source amplifier from a first voltage to a second voltage lower than the first voltage, thereby reducing the bandwidth and increasing the phase margin.

The display driver 540 according to some example embodiments may connect a load circuit including a load element of at least one of a switch, a resistor, and a capacitor to the output stage of the source amplifier, while the input terminal and the plurality of output terminals of the demultiplexer are disconnected from each other, thereby increasing the phase margin. Thus, the phase margin of the display driver 540 may be increased, and unnecessary power consumption caused by the generation of dynamic current may be prevented, thereby improving the performance of the display driver 540.

According to example embodiments of the present inventive concepts, a load circuit including load elements may be connected to an output stage of a source amplifier while an input terminal and a plurality of output terminals of a demultiplexer are disconnected from each other, thereby reducing a bandwidth and increasing a phase margin. In addition, unnecessary power consumption caused by dynamic current may be reduced, thereby improving the performance and reliability of a display driver.

While example embodiments have been shown and described above, it will be apparent to those skilled in the art that modifications and variations could be made without departing from the scope of the present disclosure as defined by the appended claims.

What is claimed is:

1. A display driver comprising:
a buffer unit configured to include a plurality of source amplifiers outputting a grayscale voltage to a plurality of source lines on a display panel, the plurality of source amplifiers respectively including an input stage and an output stage outputting the grayscale voltage;
a demultiplexer unit configured to include a plurality of demultiplexers connected between the plurality of source amplifiers and the plurality of source lines, the plurality of demultiplexers respectively having an input terminal connected to the output stage, and a plurality of output terminals connected to two or more source lines, among the plurality of source lines;
a load circuit configured to include load elements connected to the output stages of the plurality of source amplifiers, while the input terminal and the plurality of output terminals are disconnected from each other in each of the plurality of demultiplexers; and
a timing controller configured to control each of the buffer unit, the demultiplexer unit, and the load circuit.

2. The display driver of claim 1, wherein the load circuit includes a first compensation capacitor and a second compensation capacitor connected in parallel with each other between the input stage and the output stage, and a compensation switch disposed between the input stage and the second compensation capacitor, and
wherein the timing controller disconnects the input terminal and the plurality of output terminals from each other in each of the plurality of demultiplexers by a demultiplexer control signal, and turns on the compensation switch by a compensation switch control signal.

3. The display driver of claim 2, wherein the first compensation capacitor and the second compensation capacitor have the same capacitance value.

4. The display driver of claim 2, wherein the timing controller connects the input terminal and the plurality of output terminals in each of the plurality of demultiplexers by the demultiplexer control signal, and turns off the compensation switch by the compensation switch control signal.

5. The display driver of claim 1, wherein
the load circuit includes a first output switch disposed between the output stage of each of the plurality of source amplifiers and the input terminal of each of the plurality of demultiplexers, and
wherein the timing controller disconnects the input terminal and the plurality of output terminals from each other in each of the plurality of demultiplexers by a demultiplexer control signal, and turns off the first output switch by a first output switch control signal.

6. The display driver of claim 5, wherein the load circuit further includes an output resistor connected in parallel with the first output switch between the output stage and the input terminal.

7. The display driver of claim 5, wherein
the load circuit further includes a second output switch connected in parallel with the first output switch between the output stage and the input terminal, and an output resistor connected between the second output switch and the input terminal, and
wherein the timing controller disconnects the input terminal and the plurality of output terminals from each other in each of the plurality of demultiplexers by the demultiplexer control signal, and turns on the second output switch by a second output switch control signal.

8. The display driver of claim 7, wherein each of the first output switch and the second output switch is implemented as a CMOS transistor.

9. The display driver of claim 7, wherein the timing controller connects the input terminal and the plurality of output terminals in each of the plurality of demultiplexers by the demultiplexer control signal, turns on the first output switch by the first output switch control signal, and turns on the second output switch by the second output switch control signal.

10. The display driver of claim 7, wherein the timing controller connects the input terminal and the plurality of output terminals in each of the plurality of demultiplexers by the demultiplexer control signal, turns on the first output switch by the first output switch control signal, and turns off the second output switch by the second output switch control signal.

11. The display driver of claim 7, wherein
the timing controller turns on the second output switch by the second output switch control signal during a display time in which data is input to the display panel, and
the timing controller turns off the second output switch by the second output switch control signal during a display porch time other than the display time.

12. The display driver of claim 1, wherein the plurality of source lines are respectively connected to a plurality of pixels, the two or more source lines include a first source line and a second source line, and a first pixel connected to the first source line and a second pixel connected to the second source line, among the plurality of pixels, have the same color filter.

13. The display driver of claim 1, wherein the plurality of source lines are respectively connected to a plurality of pixels, the two or more source lines include a first source line and a second source line, and a first pixel connected to the first source line and a second pixel connected to the second source line, among the plurality of pixels, have different color filters.

14. The display driver of claim 1, further comprising:
a bias voltage circuit configured to include a first PMOS transistor and a first buffer connected in series with each other, and a first NMOS transistor and a second buffer connected in series with each other,
wherein the first PMOS transistor and the first buffer are connected to a power supply voltage, and the first NMOS transistor and the second buffer are connected to a ground voltage, and
the bias voltage circuit is configured to reduce a bias voltage from a first voltage to a second voltage, lower than the first voltage, while the input terminal and the plurality of output terminals are disconnected from each other in each of the plurality of demultiplexers.

15. The display driver of claim 14, wherein the first voltage is three times the second voltage.

16. The display driver of claim 14, wherein the bias voltage circuit is configured to increase the bias voltage from the second voltage to the first voltage before the timing controller connects the input terminal and the plurality of output terminals in each of the plurality of the demultiplexers by a demultiplexer control signal.

17. A display driver comprising:
an output pad configured to be connected to two or more source lines, among a plurality of source lines disposed on a display panel, the plurality of source lines respectively connected to a plurality of pixels;
a source amplifier configured to generate a grayscale voltage for one selection pixel, among the plurality of pixels, using at least one gamma voltage;
a demultiplexer configured to be connected between the output pad and the plurality of source lines, configured to be connected to the two or more source lines, and configured to transmit the grayscale voltage to the one selection pixel; and
a load circuit between the output pad and the source amplifier, configured to include load elements,
wherein the source amplifier is configured to output a first grayscale voltage for a first pixel, among the plurality of pixels, to the demultiplexer, and output a second grayscale voltage for a second pixel, among the plurality of pixels, to the demultiplexer,
the demultiplexer is configured to transmit the first grayscale voltage to a first source line, among the plurality of source lines, during a first time, transmit the second grayscale voltage to a second source line, among the plurality of source lines, during a second time after the first time, and be disconnected from the two or more source lines during a third time after the second time, and
the source amplifier and the load circuit are connected to each other during the third time.

18. The display driver of claim 17, wherein an interval between the first time and the second time is shorter than the third time.

19. The display driver of claim 17, wherein the load elements include one or more of a switch, a resistor, and a capacitor.

20. A display driver comprising:
an output pad configured to be connected to two or more source lines, among a plurality of source lines on a display panel, the plurality of source lines respectively connected to a plurality of pixels;
a source amplifier configured to generate a grayscale voltage for one selection pixel, among the plurality of pixels, using at least one gamma voltage;
a demultiplexer configured to be connected between the output pad and the plurality of source lines, configured to be connected to the two or more source lines, and configured to transmit the grayscale voltage to the one selection pixel;
a bias voltage circuit configured to include a first PMOS transistor and a first buffer connected to a power supply voltage of the source amplifier, and a first NMOS transistor and a second buffer connected to a ground voltage; and
a load circuit configured to include a first output switch connected between the source amplifier and the output pad, a second output switch and an output resistor connected in parallel with the first output switch, and a compensation capacitor and a compensation switch connected to a feedback path of the source amplifier,
wherein the bias voltage circuit is configured to reduce a bias voltage from a first voltage to a second voltage, lower than the first voltage, the first output switch is turned off, the second output switch is turned on, and the compensation switch is turned on, while the demultiplexer is disconnected from the two or more source lines.
